(19) United States
(12) Patent Application Publication
(10) Pub. No.: US 2026/0033175 A1
(43) Pub. Date: Jan. 29, 2026

(54) DISPLAY PANEL AND DISPLAY DEVICE

(71) Applicant: HKC CORPORATION LIMITED, SHENZHEN (CN)

(72) Inventors: Fengzhen DANG, SHENZHEN (CN); Chuan WU, SHENZHEN (CN); Zhonglin CAO, SHENZHEN (CN); Yao LI, SHENZHEN (CN); Dongmei WEI, SHENZHEN (CN); Xiaoxiao YUAN, SHENZHEN (CN); Wenyu YI, SHENZHEN (CN); Jie CHEN, SHENZHEN (CN); Lidan YE, SHENZHEN (CN)

(73) Assignee: HKC CORPORATION LIMITED, SHENZHEN (CN)

(21) Appl. No.: 19/268,005

(22) Filed: Jul. 14, 2025

(30) Foreign Application Priority Data
Jul. 23, 2024 (CN) 202410996887.8

(51) Int. Cl. H10K 59/127; H10K 59/12; H10K 59/131

(52) U.S. Cl. CPC H10K 59/1275; H10K 59/1201; H10K 59/131

(57) ABSTRACT

A display panel and a display device are provided. The display panel includes a silicon-based driving substrate, a glass substrate, and an organic light-emitting display device. The glass substrate is disposed on a side of the silicon-based driving substrate and define a plurality of first vias. An organic light-emitting display device may be disposed on a side of the glass substrate away from the silicon-based driving substrate and bonded to the silicon-based driving substrate through at least one of the plurality of first vias.

### CROSS-REFERENCE TO RELATED APPLICATIONS

This application claims priority to Chinese Patent Application No. 202410996887.8, filed on Jul. 23, 2024 in the National Intellectual Property Administration of China, the contents of which are herein incorporated by reference in their entireties.

### TECHNICAL FIELD

The present disclosure relates to the field of display technology, and in particular to a display panel and a display device.

### BACKGROUND

Virtual Reality (VR) is a technology primarily based on computer technology, which utilizes and integrates the latest advancements in high-tech fields such as three-dimensional graphics technology, multimedia technology, simulation technology, display technology, and servo technology, and etc. With the help of computers and other devices, the VR generates a realistic virtual world that provides multi-sensory experiences including three-dimensional visual, tactile, olfactory sensations, and etc., thereby creating an immersive experience for users within the virtual environment.

Augmented Reality (AR) is a technology that skillfully integrates virtual information with the real world. The AR extensively applies a variety of technical means such as multimedia, three-dimensional modeling, real-time tracking and registration, intelligent interaction, and sensing technologies, and etc. After simulating and rendering virtual information generated by computers, including text, images, three-dimensional models, music, video, and etc., the AR applies the virtual information to the real world. Both information complement each other to achieve an “enhancement” of the real world.

A silicon-based organic light emitting diode (OLED) is currently a type of display device with the best performance in AR/VR products. Compared with conventional active-matrix organic light-emitting diode (AMOLED) devices that use amorphous silicon, microcrystalline silicon, or low-temperature polysilicon thin-film transistors as a backplane, a monocrystalline silicon backplane may have higher carrier mobility.

During a process of evaporating organic layers, silicon-based driving circuits may be prone to being affected, which may lead to malfunction of the driving circuits and increased costs.

### SUMMARY OF THE DISCLOSURE

In order to address the technical problem above, some embodiments of the present disclosure may provide a display panel and a display device, which reduces a cost of manufacturing or preparing a silicon-based driving substrate.

A technical solution of the present disclosure may provide a display panel. The display panel may include a silicon-based driving substrate, a glass substrate, and an organic light-emitting display device. The glass substrate may be disposed on a side of the silicon-based driving substrate and define a plurality of first vias. An organic light-emitting display device may be disposed on a side of the glass substrate away from the silicon-based driving substrate and bonded to the silicon-based driving substrate through at least one of the plurality of first vias.

Another technical solution of the present disclosure may provide a method of manufacturing a display panel. The method may include: providing a silicon-based driving substrate and a glass substrate, where one or more first bumps may be disposed on a side of the silicon-based driving substrate; defining a plurality of first vias on the glass substrate; filling the plurality of first vias to form one or more second bumps on a side of the glass substrate; forming an organic light-emitting display device on a side of the glass substrate away from the one or more second bumps, where the organic light-emitting display device may be connected to each of the one or more second bumps through a corresponding one of the plurality of first vias; and connecting the one or more first bumps to the one or more second bumps to bond the silicon-based driving substrate with the organic light-emitting display device.

Still another technical solution of the present disclosure may provide a display device. The display device may include a display panel and a power supply configured to supply power to the display panel. The display panel may be the aforementioned display panel or a display panel manufactured through the aforementioned method.

### BRIEF DESCRIPTION OF THE DRAWINGS

In order to more clearly illustrate the technical solutions in some embodiments of the present disclosure, a brief introduction will be given below to the drawings required in the description of the embodiments. It is evident that the drawings described below are merely some embodiments of the present disclosure, and those skills in the art may obtain other drawings based on the following drawings without creative work.

FIG. 1 is a schematic structural view of a first embodiment of a display panel according to the present disclosure.

FIG. 2 is a schematic view of a laser-induced modification etching according to some embodiments of the present disclosure.

FIG. 3 is a schematic structural view of a second embodiment of the display panel according to the present disclosure.

FIG. 4 is a schematic structural view of a silicon-based driving substrate according to some embodiments of the present disclosure.

FIG. 5 is a schematic structural view of an organic light-emitting display device according to some embodiments of the present disclosure.

FIG. 6 is a schematic view illustrating a bonding of a silicon-based driving substrate and an organic light-emitting display device according to some embodiments of the present disclosure.

FIG. 7 is a flowchart illustrating a method of manufacturing a display panel according to some embodiments of the present disclosure.

FIG. 8 is a flowchart illustrating operation 71 according to some embodiments of the present disclosure.

FIG. 9a is a first schematic structural view illustrating operation 712 according to some embodiments of the present disclosure.

FIG. 9b is a second schematic structural view illustrating operation 712 according to some embodiments of the present disclosure.

FIG. 9c is a schematic structural view illustrating operation 713 according to some embodiments of the present disclosure.

FIG. 9d is a schematic structural view illustrating operation 714 according to some embodiments of the present disclosure.

FIG. 10 is a schematic structural view illustrating operation 74 according to some embodiments of the present disclosure.

FIG. 11a is a schematic structural view illustrating operation 741 according to some embodiments of the present disclosure.

FIG. 11b is a schematic structural view illustrating a connection manner of a second electrode according to some embodiments of the present disclosure.

FIG. 11c is a schematic structural view illustrating another manufacturing process of operation 74 according to some embodiments of the present disclosure.

FIG. 12 is a schematic structural view of a display device according to some embodiments of the present disclosure.

### DETAILED DESCRIPTION

Some technical solutions of the embodiments of the present disclosure will be clearly and thoroughly described below in conjunction with the accompanying drawings. It should be understood that the embodiments described herein are intended only to illustrate the present disclosure, and are not intended to limit the present disclosure. It should further be noted that, for ease of description, the drawings only show the portions relevant to the present disclosure rather than the entire structure. Based on the embodiments of the present disclosure, all other embodiments that can be obtained by those skills in the art without creative effort shall fall within the scope of protection of the present disclosure.

The terms “first,” “second” and etc., in the present disclosure are used to distinguish between different objects and are not intended to denote any specific sequence. In addition, the terms “comprising” “including” “having” and any variations thereof are intended to cover non-exclusive inclusions. For example, a process, method, system, product, or device that includes a series of steps or units is not limited to only those steps or units that are listed, but may optionally include other steps or units not listed, or may optionally include inherent steps or units of such process, method, product, or device.

References to “embodiments” herein mean that specific features, structures, or characteristics described in connection with the embodiments may be included in at least one embodiment of the present disclosure. The appearances of the phrase at various places in the specification are not necessarily all referring to the same embodiment, and are not mutually exclusive of other embodiments. It is explicitly and implicitly understood by those skills in the art that the described embodiments may be combined with other embodiments.

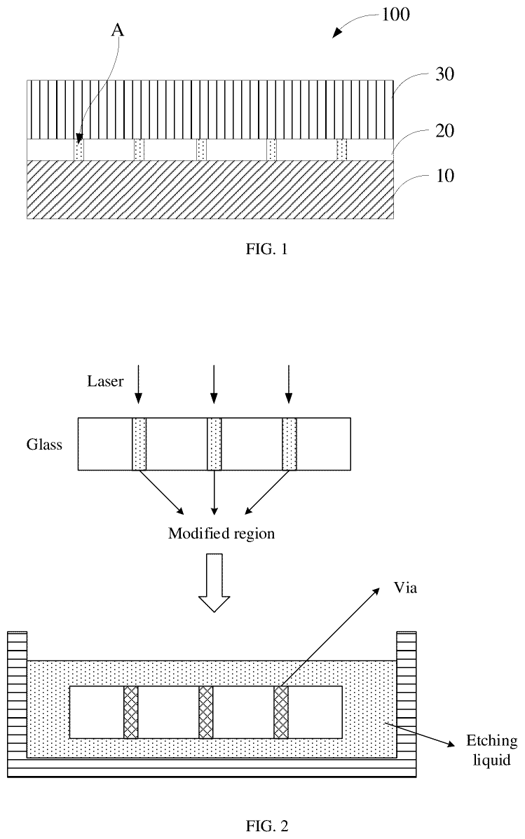

As shown in FIG. 1, FIG. 1 is a schematic structural view of a first embodiment of a display panel according to the present disclosure. The display panel 100 may include a silicon-based driving substrate 10, a glass substrate 20, and an organic light-emitting display device 30.

The glass substrate 20 may be disposed on a side of the silicon-based driving substrate 10. The organic light-emitting display device 30 may be disposed on a side of the glass substrate 20 away from the silicon-based driving substrate 10. That is, the silicon-based driving substrate 10 and the organic light-emitting display device 30 may be disposed on two opposite sides of the glass substrate 20.

A plurality of first vias A may be defined on the glass substrate 20. The organic light-emitting display device 30 and the silicon-based driving substrate 10 may be bonded through at least one of the plurality of first vias A.

In some embodiments, the first via A may be formed or defined on the glass substrate 20 through a Through Glass Via (TGV) process. The TGV may refer to a process of penetrating through the glass substrate 20 to create a vertical electrical interconnection.

During a conventional process, a Through Silicon Via (TSV) process may be generally adopted. Both the TSV and the TGV may be applied in the field of 2.5D or 3D interposers. However, the TSV process may pose two main issues. 1) High cost, i.e., the TSV process may involve a silicon etching process and require technologies such as oxide insulation layers and handling of thin wafers. 2) Poor electrical performance, i.e., since silicon is a semiconductor material, during a signal transmission line transmitting signal, the signal may experience strong electromagnetic coupling with a substrate material, resulting in eddy currents in the substrate and poor signal integrity (e.g., insertion loss, crosstalk, and etc.). In contrast, the TGV process may provide the following advantages.
1) Excellent high-frequency electrical characteristics. Glass is an insulating material. A dielectric constant of the glass may be about one-third of a dielectric constant of the silicon. A loss factor of the glass may be 2 to 3 orders of magnitude lower than a loss factor of the silicon. In this way, a substrate loss and a parasitic effect may be greatly reduced, thereby ensuring signal transmission integrity.
2) A large-size ultra-thin glass substrate is readily available. Currently, a panel glass that has an extra-large size dimension (over 2 m×2 m in length×width) and a thickness less than 50 μm and an ultra-thin flexible glass material are available.
3) Low cost. Thanks to the availability of the large-size ultra-thin panel glass and an unnecessariness of depositing an insulating layer, a manufacturing cost of the glass interposers may be approximately one-eighth of a manufacturing cost of the silicon-based interposers.
4) Simple process flow. The insulating layer may no longer need to be deposited on a surface of the substrate or an inner wall of the TGV. In addition, the ultra-thin interposers may not be required for thinning.
5) Strong mechanical stability. Even when the thickness of the interposers is less than 100 μm, a warpage may remain small.
6) Wide range of applications. In addition to the promising use in high-frequency fields, as glass is a transparent material, the TGV process may be further used in the field of optoelectronic system integration. The advantages, such as hermeticity and corrosion resistance, may render the glass substrate to be highly promising in micro-electro-Mechanical system (MEMS) packaging.

During the process of manufacturing or preparing the first via A through the TGV process, a commonly used method may include a mechanical drilling, a dry etching, a wet etching, a focused ion beam, a laser ablation, a laser-induced modification, and etc. The following will illustrate the laser ablation and the laser-induced modification as examples.

The laser ablation may refer to a process in which glass atoms undergo high-frequency oscillation and rapid heating when excited by laser, which causes the atoms to be detached from the substrate, melted, and vaporized. The molten products and residues from the laser ablation may be adhered to an opening of the deep via and need to be removed after the etching is completed.

The laser-induced modification etching may involve using ultra-short pulse lasers (with pulse durations in the picosecond range) to induce the formation of continuous modified regions in the glass. Compared to unmodified glass, the modified glass may be etched more rapidly in hydrofluoric acid. Such process may not produce cracks in the glass and may allow for the formation of a blind via and a through via. Advanced laser-induced etching technology may create a high aspect ratio (i.e., depth-to-width ratio) structure. A typical TGV diameter currently may range from 20-100 μm, with an aspect ratio from 1:4 to 1:10.

As shown in FIG. 2, FIG. 2 is a schematic view of a laser-induced modification etching according to some embodiments of the present disclosure. The Laser-induced modification etching may include the following two operations.

Firstly, using an ultra-short pulse laser to form a modified region on a glass.

Secondly, placing the laser-treated glass into hydrofluoric acid solution for etching.

In the above embodiments, the silicon-based driving substrate 10 may further be referred to as a silicon-based CMOS driving substrate. The silicon-based driving substrate 10 may include a silicon substrate and a driving circuit manufactured or prepared on the silicon substrate. The driving circuit may be manufactured or prepared through a CMOS integrated circuit process. A feature size of a transistor of the driving circuit may include 0.6 μm, 0.5 μm, 0.35 μm, 0.25 μm, 0.18 μm, 0.13 μm, or other typical deep submicron process sizes. The driving circuit may support dual-voltage or multi-voltage regions, with an analog circuit voltage ranges from −5V to +5V and a digital circuit voltage from +1V to +5V.

In some embodiment, the driving circuit may be manufactured or prepared on the silicon substrate to form a driving chip wafer. The driving chip wafer may then be diced into wafer dies. Each wafer die may correspond to one sub-pixel.

In the above embodiments, the organic light-emitting display device 30 may be an OLED device. The OLED device may include an anode, a light-emitting layer, and a cathode. Bonding the silicon-based driving substrate 10 with the organic light-emitting display device 30 may refer to connecting the cathode and/or the anode to the above-mentioned driving circuit (the wafer dies) through the first via A on the glass substrate 20.

The display panel provided by some embodiments of the present disclosure may include: a silicon-based driving substrate; a glass substrate, disposed on a side of the silicon-based driving substrate and defining a first via; and an organic light-emitting display device, disposed on a side of the glass substrate away from the silicon-based driving substrate and bonded to the silicon-based driving substrate through the first via. In this way, in a first aspect, the glass substrate may isolate the silicon-based driving substrate from the organic light-emitting display device, allowing or enabling the silicon-based driving substrate and the organic light-emitting display device to be manufactured or prepared separately. That is, the organic light-emitting display device may be manufactured or prepared on the glass substrate rather than directly on the silicon-based driving substrate, thereby reducing damage to the silicon-based driving substrate during the manufacture or preparation of the organic light-emitting display device. In a second aspect, the organic light-emitting display device may be bonded to the silicon-based driving substrate through the first via on the glass substrate. In this case, the TGV technology may provide advantages over the TSV technology, including excellent high-frequency electrical characteristics, low cost, simple process, strong mechanical stability, and etc.

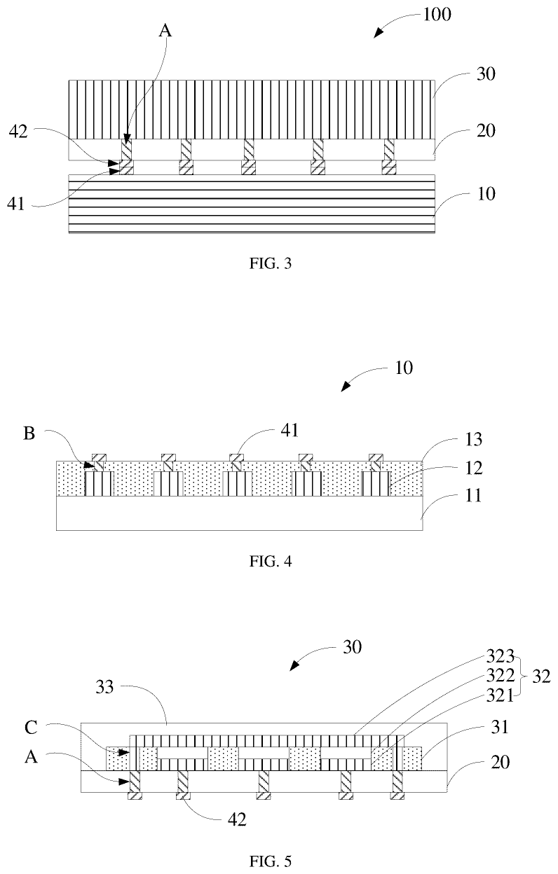

As shown in FIG. 3, FIG. 3 is a schematic structural view of a second embodiment of the display panel according to the present disclosure. The display panel 100 may include a silicon-based driving substrate 10, a glass substrate 20, and an organic light-emitting display device 30.

The glass substrate 20 may be disposed on a side of the silicon-based driving substrate 10. The organic light-emitting display device 30 may be disposed on a side of the glass substrate 20 away from the silicon-based driving substrate 10. That is, the silicon-based driving substrate 10 and the organic light-emitting display device 30 may be respectively disposed on opposite sides of the glass substrate 20.

One or more first bumps or protrusions 41 may be disposed on a side of the silicon-based driving substrate 10 facing the glass substrate 20. One or more second bumps or protrusions 42 may be disposed on a side of the glass substrate 20 facing the silicon-based driving substrate 10. Each of the one or more second bumps 42 may be connected to the organic light-emitting display device 30 through a corresponding one of the first vias A. Each of the one or more first bumps 41 and a corresponding one of the one or more second bumps 42 may be connected to each other, enabling the organic light-emitting display device 30 to be bonded with the silicon-based driving substrate 10. The first bump 41 and the second bump 42 may be both made of a conductive material. The second bump 42 may be formed during a filling process of the first via A. It can be understood that, during a separate manufacture of preparation of the organic light-emitting display device 30, the TGV process may be first applied to the glass substrate 20 to form or define a via, such that the first via corresponding to each sub-pixel may be formed. Then, the first via may be filled, and the second bump 42 may be disposed on a side of the glass substrate 20. Subsequently, the organic light-emitting display device 30 may be manufactured or prepared on another side of the glass substrate 20 that is away from the second bump 42.

The following may describe the silicon-based driving substrate 10 and the organic light-emitting display device 30, respectively.

As shown in FIG. 4, FIG. 4 is a schematic structural view of a silicon-based driving substrate according to some embodiments of the present disclosure. The silicon-based driving substrate 10 may include a silicon substrate 11, a driving device 12, and a protection layer 13.

The driving device 12 may be disposed on a side of the silicon substrate 11 facing the glass substrate 20. The protection layer 13 may cover the driving device 12. One or more second vias B may be defined on the protection layer 13. Each of the one or more first bumps 41 may be connected to the driving device 12 through a corresponding one of the one or more second vias B.

In some embodiments, the driving device 12 may be a CMOS device. In some embodiments, a driving circuit may be manufactured or prepared on the silicon substrate 11 to form a driver chip wafer. Then, the driver chip wafer may be diced to form a plurality of above-mentioned driving devices 12.

In some embodiments, the second via B may be formed or defined on the protection layer 13 through a mask etching process. Then, a conductive material may be deposited on the protection layer 13 to form a conductive layer. The conductive material may be filled into the second via B. Subsequently, the conductive layer may be treated using the mask etching process to form the first bump 41 corresponding to each driving device 12.

As shown in FIG. 5, FIG. 5 is a schematic structural view of an organic light-emitting display device according to some embodiments of the present disclosure. The organic light-emitting display device 30 may include a spacer structure 31, a plurality of sub-pixels 32, and an encapsulation layer 33.

The spacer structure 31 may be disposed on a side of the glass substrate 20 away from the silicon-based driving substrate 10. The spacer structure 31 may define a plurality of pixel openings. The plurality of sub-pixels 32 may be disposed in the plurality of pixel openings in one-to-one correspondence. It can be understood that, the spacer structure 31 may be configured to define positions of the plurality of sub-pixels 32. In some embodiments, the spacer structure 31 may include a pixel defining layer at a lower level and a spacer portion at an upper level.

For each sub-pixel 32, the sub-pixel 32 may include a first electrode 321, a light-emitting device 322, and a second electrode 323. The second electrode 323 may be shared by at least part of the plurality of sub-pixels 32. The first electrode 321 may be disposed on a side of the glass substrate 20 away from the silicon-based driving substrate 10. The first electrode 321 may be connected to the second bump 42 through the corresponding one first via A. The light-emitting device 322 may be disposed on a side of the first electrode 321 away from the glass substrate 20. The second electrode 323 may be disposed on a side of the light-emitting device 322 away from the first electrode 321. The second electrode 323 may be connected to at least one second bump 42 respectively through at least one first via A.

In some embodiments, the first electrode 321 may be an anode and the second electrode 323 may be a cathode. The first electrode 321 and the second electrode 323 may be made of titanium, aluminum, copper, and etc. Since light may be emitted from a side of the organic light-emitting display device 30, the corresponding electrode on the side of the organic light-emitting display device 30 that the light is emitted from may be made of a conductive polymer or an indium tin oxide (ITO), and etc.

In some embodiments, a third via C may be defined on the spacer structure 31. The third via C may be in communication with one first via A. The second electrode 323 may be connected to a corresponding one of the at least one second bump 42 through the corresponding one third via C and the corresponding one first via A.

It can be understood that, taking a RGB three-color pixel as an example, a width of the spacer structure between any two of three sub-pixels in a single pixel may be relatively small, while the spacer structure between two adjacent pixels may be relatively large. The third via C may be defined on the spacer structure between two adjacent pixels, thereby realizing the connection between the first electrode 321 and the second bump 42 and the connection between the second electrode 323 and the second bump 42.

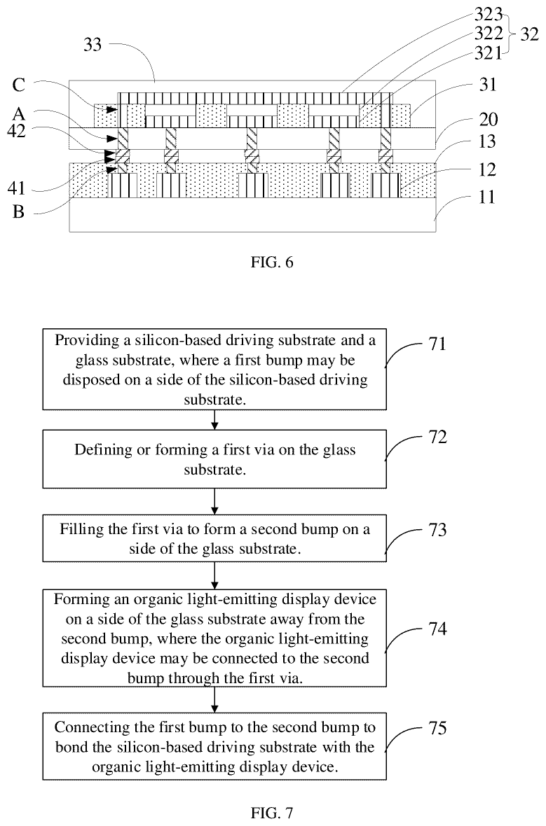

In combination with FIG. 4 and FIG. 5, as shown in FIG. 6, FIG. 6 is a schematic view illustrating a bonding of a silicon-based driving substrate and an organic light-emitting display device according to some embodiments of the present disclosure. It can be understood that, the first bumps 41 on the silicon-based driving substrate 10 and the second bumps 42 on the glass substrate 20 may be in one-to-one correspondence. During the bonding, each first bump 41 and the corresponding one second bump 42 may be soldered with each other.

As shown in FIG. 7, FIG. 7 is a flowchart illustrating a method of manufacturing a display panel according to some embodiments of the present disclosure. A method of manufacturing a display panel may include the following operations.

At operation 71: providing a silicon-based driving substrate and a glass substrate. A first bump may be disposed on a side of the silicon-based driving substrate.

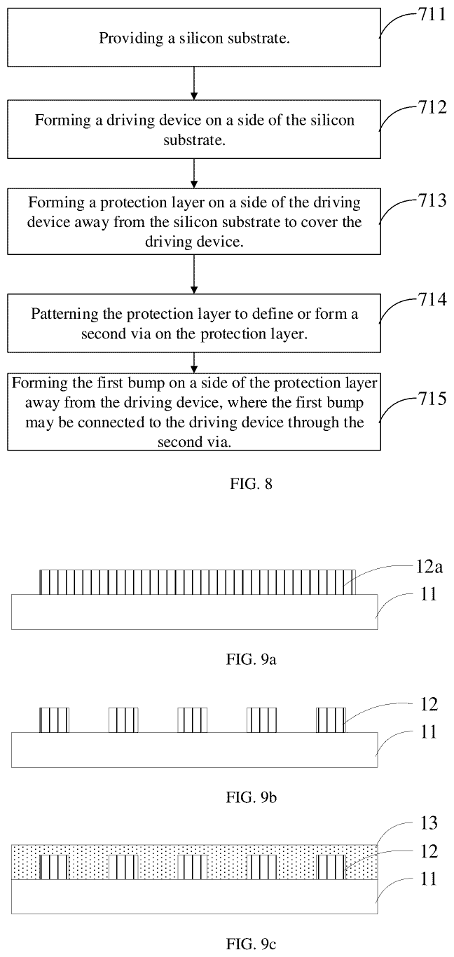

In some embodiments, as shown in FIG. 8, FIG. 8 is a flowchart illustrating operation 71 according to some embodiments of the present disclosure. A process of providing a silicon-based driving substrate may include the following operations.

At operation 711: providing a silicon substrate.

In some embodiments, the silicon substrate may be a monocrystalline silicon.

At operation 712: forming a driving device on a side of the silicon substrate.

In some embodiments, the driving device may be a CMOS device.

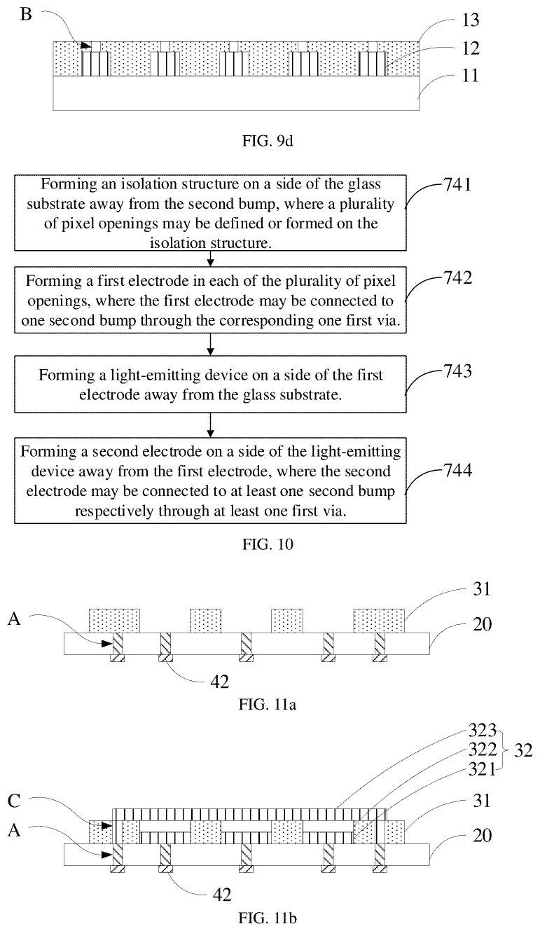

In some embodiments, as shown in FIGS. 9a and 9b, FIG. 9a is a first schematic structural view illustrating operation 712 according to some embodiments of the present disclosure, and FIG. 9b is a second schematic structural view illustrating operation 712 according to some embodiments of the present disclosure. The driver circuit may be manufactured or prepared on the silicon substrate 11 to form a driver chip wafer 12a. The driver chip wafer 12a may then be diced into wafer dies, i.e., the driving devices 12.

At operation 713: forming a protection layer on a side of the driving device away from the silicon substrate to cover the driving device.

As shown in FIG. 9c, FIG. 9c is a schematic structural view illustrating operation 713 according to some embodiments of the present disclosure. In some embodiments, the protection layer 13 may cover the driving device 12 and a part of the silicon substrate 11 that is exposed from the driving device 12.

At operation 714: patterning the protection layer to define or form a second via on the protection layer.

As shown in FIG. 9d, FIG. 9d is a schematic structural view illustrating operation 714 according to some embodiments of the present disclosure. The protection layer 13 may be patterned to form or define a second via B on the protection layer 13.

At operation 715: forming the first bump on a side of the protection layer away from the driving device. The first bump may be connected to the driving device through the second via.

As shown in FIG. 4, the first bump 41 may be formed on a side of the protection layer 13 away from the driving device 12. The first bump 41 may be connected to the driving device 12 through the second via B.

At operation 72: defining or forming a first via on the glass substrate.

The operation 72 may generally adopt the TGV process. During the process of forming or defining the first via A through the TGV process, a commonly used method may include a mechanical drilling, a dry etching, a wet etching, a focused ion beam, a laser ablation, a laser-induced modification, and etc. The following will illustrate the laser ablation and the laser-induced modification as examples.

The laser ablation may refer to a process in which glass atoms undergo high-frequency oscillation and rapid heating when excited by laser, which causes the atoms to be detached from the substrate, melted, and vaporized. The molten products and residues from the laser ablation may be adhered to an opening of the deep via and need to be removed after the etching is completed.

The laser-induced modification etching may involve using ultra-short pulse lasers (with pulse durations in the picosecond range) to induce the formation of continuous modified regions in the glass. Compared to unmodified glass, the modified glass may be etched more rapidly in hydrofluoric acid. Such process may not produce cracks in the glass and may allow for the formation of a blind via and a through via. Advanced laser-induced etching technology may create a high aspect ratio (i.e., depth-to-width ratio) structure. A typical TGV diameter currently may range from 20-100 μm, with an aspect ratio from 1:4 to 1:10.

As shown in FIG. 2, FIG. 2 is a schematic view of laser-induced modification etching according to some embodiments of the present disclosure. The Laser-induced modification etching may include the following two operations.

Firstly, using an ultra-short pulse laser to form a modified region on a glass.

Secondly, placing the laser-treated glass into hydrofluoric acid solution for etching.

In the above embodiments, the silicon-based driving substrate 10 may further be referred to as a silicon-based CMOS driving substrate. The silicon-based driving substrate 10 may include a silicon substrate and a driving circuit manufactured or prepared on the silicon substrate. The driving circuit may be manufactured or prepared through a CMOS integrated circuit process. A feature size of a transistor of the driving circuit may include 0.6 μm, 0.5 μm, 0.35 μm, 0.25 μm, 0.18 μm, 0.13 μm, or other typical deep submicron process sizes. The driving circuit may support dual-voltage or multi-voltage regions, with an analog circuit voltage ranges from −5V to +5V and a digital circuit voltage from +1V to +5V.

At operation 73: filling the first via to form a second bump on a side of the glass substrate.

It can be understood that, the second bump may be formed through filling the conductive material at the operation 73.

At operation 74: forming an organic light-emitting display device on a side of the glass substrate away from the second bump. The organic light-emitting display device may be connected to the second bump through the first via.

In some embodiments, as shown in FIG. 10, FIG. 10 is a schematic structural view illustrating operation 74 according to some embodiments of the present disclosure. The operation 74 may include the following operations.

At operation 741: forming a spacer structure on a side of the glass substrate away from the second bump. A plurality of pixel openings may be defined or formed on the spacer structure.

In some embodiments, as shown in FIG. 11a, FIG. 11a is a schematic structural view illustrating operation 741 according to some embodiments of the present disclosure. The spacer structure 31 may be first formed on a side of the glass substrate 20 away from the second bump 42. The plurality of pixel openings may be defined or formed on the spacer structure 31. Then, the first electrode 321, the light-emitting device 322, the second electrode 323, and etc. may be subsequently prepared or manufactured.

At operation 742: forming a first electrode in each of the plurality of pixel openings. The first electrode may be connected to one second bump through the corresponding one first via.

At operation 743: forming a light-emitting device on a side of the first electrode away from the glass substrate.

At operation 744: forming a second electrode on a side of the light-emitting device away from the first electrode. The second electrode may be connected to at least one second bump respectively through at least one first via.

The above operations 742 to 744 may sequentially manufacture or prepare the first electrode 321, the light-emitting device 322, and the second electrode 323, which will not be repeated herein.

In some embodiments, as shown in FIG. 11b, FIG. 11b is a schematic structural view illustrating a connection manner of a second electrode according to some embodiments of the present disclosure. The third via C may be formed or defined on the spacer structure 31. The third via C may be in communication with one first via A. The second electrode 323 may be connected to a corresponding one of the at least one second bump 42 through the corresponding one third via C and the corresponding one first via A.

Apart from the preparation or manufacture sequence of the above operations 741 to 744, in some other embodiments, as shown in FIG. 11c, FIG. 11c is a schematic structural view illustrating another manufacturing process of operation 74 according to some embodiments of the present disclosure. The first electrode 321 may be first formed on a side of the glass substrate 20 away from the second bump 42. Then, the spacer structure 31 may be formed on the side of the glass substrate 20 away from the second bump 42. The plurality of pixel openings may be defined or formed on the spacer structure 31. The light-emitting device 322 and the second electrode 323 may be subsequently prepared or manufactured. It should be understood that in some embodiments, a part of the spacer structure 31 may lap with an edge of the first electrode 321.

At operation 75: connecting the first bump to the second bump to bond the silicon-based driving substrate with the organic light-emitting display device.

According to the above mentioned method, some embodiments of the present disclosure may allow for the manufacture or preparation of display pixels of smaller pixel sizes and the realization of refined display pixels. A pixel size of the silicon-based CMOS driving substrate may be typically in a range of 6-15 μm, which may be one-tenth of a pixel size of a traditional display device or even smaller than, and a pixel density of the silicon-based CMOS driving substrate may be more than ten times higher than a pixel density of the traditional device, thereby achieving a display refinement that surpasses retinal-level resolution. The silicon-based CMOS driving substrate may offer numerous advantages such as high resolution, high integration, low power consumption, small size, and light weight, etc.

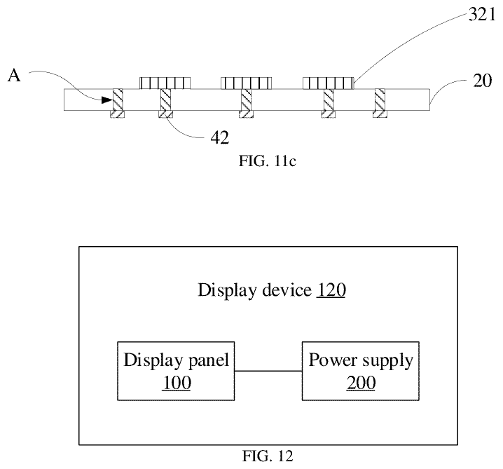

FIG. 12 is a schematic structural view of a display device according to some embodiments of the present disclosure. The display device 120 may include a display panel 100 and a power supply 200. The power supply 200 may be configured to supply power to the display panel 100. The display panel 100 may be the display panel in the above-mentioned embodiments.

In some application scenarios, the display device 120 may be configured in a micro display, such as an AR/VR device.

In some embodiments of the present disclosure, it can be understood that the disclosed methods and devices may be implemented in other ways. For example, the above-described device embodiments are merely illustrative. The division of modules or units is only based on logical functions, and other divisions may be used in practical implementation. For example, multiple units or components may be combined or integrated into another system, or certain features may be omitted or not performed.

The units described as separate components may or may not be physically separate. Components presented as individual units may or may not be physical entities, that is, may be located at a single site or distributed across multiple network entities. Some or all of the units may be selectively employed, as needed, to achieve the objectives of the embodiments of the present disclosure.

In addition, the functional units described in the various embodiments of the present disclosure may be integrated into a single processing unit, may exist independently as separate physical units, or two or more units may be integrated into a single entity. Such integrated units may be implemented in hardware form or in the form of software functional modules.

The above are merely exemplary embodiments of the present disclosure and should not be construed as limiting the scope of the present disclosure. Based on the description and drawings of the present disclosure, any equivalent structural or process modifications, or any direct or indirect applications in other related technical fields, shall fall within the scope of the present disclosure.

1. A display panel, comprising:
a silicon-based driving substrate;
a glass substrate, disposed on a side of the silicon-based driving substrate and defining a plurality of first vias; and
an organic light-emitting display device, disposed on a side of the glass substrate away from the silicon-based driving substrate and bonded to the silicon-based driving substrate through at least one of the plurality of first vias.

2. The display panel as claimed in claim 1, wherein one or more first bumps are disposed on a side of the silicon-based driving substrate facing the glass substrate, one or more second bumps are disposed on a side of the glass substrate facing the silicon-based driving substrate, each of the one or more second bumps is connected to the organic light-emitting display device through a corresponding one of the plurality of first vias, and each of the one or more first bumps is connected to a corresponding one of the one or more second bumps, enabling the organic light-emitting display device to be bonded with the silicon-based driving substrate.

3. The display panel as claimed in claim 2, wherein the silicon-based driving substrate comprises:
a silicon substrate;
a driving device, disposed on a side of the silicon substrate facing the glass substrate; and
a protection layer, covering the driving device and defining one or more second vias, wherein each of the one or more first bumps is connected to the driving device through a corresponding one of the one or more second vias.

4. The display panel as claimed in claim 2, wherein the plurality of first vias comprise one or more first sub-vias and one or more second sub-vias, and the organic light-emitting display device comprises:
a spacer structure, disposed on a side of the glass substrate away from the silicon-based driving substrate and defining a plurality of pixel openings; and
a plurality of sub-pixels, disposed in the plurality of pixel openings, and each of the plurality of sub-pixels corresponding to one of the one or more first sub-vias.

5. The display panel as claimed in claim 4, wherein the one or more second bumps comprise a first sub-bump and at least one second sub-bump, and each of the plurality of sub-pixels comprises:
a first electrode, disposed on a side of the glass substrate away from the silicon-based driving substrate and connected to the first sub-bump through a corresponding one of the one or more first sub-vias;
a light-emitting device, disposed on a side of the first electrode away from the glass substrate; and
a second electrode, disposed on a side of the light-emitting device away from the first electrode and connected to the at least one second sub-bump respectively through the one or more second sub-vias.

6. The display panel as claimed in claim 5, wherein a third via is defined on the spacer structure, the third via is in communication with a corresponding one of the more than one second sub-vias, and the second electrode is connected to a corresponding one of the at least one second sub-bump through the third via and the corresponding one of the more than one second sub-vias.

7. The display panel as claimed in claim 2, wherein each of the one or more first bumps and each of the one or more second bumps are both made of a conductive material.

8. The display panel as claimed in claim 6, wherein the organic light-emitting display device further comprises a plurality of pixel units, each of the plurality of pixel units comprises more than one of the plurality of sub-pixels that are adjacent to each other, and the third via is defined on the spacer structure between any adjacent two of the plurality of pixel units.

9. A method of manufacturing a display panel, comprising:
providing a silicon-based driving substrate and a glass substrate, wherein one or more first bumps are disposed on a side of the silicon-based driving substrate;
defining a plurality of first vias on the glass substrate;
filling the plurality of first vias to form one or more second bumps on a side of the glass substrate;
forming an organic light-emitting display device on a side of the glass substrate away from the one or more second bumps, wherein the organic light-emitting display device is connected to each of the one or more second bumps through a corresponding one of the plurality of first vias; and
connecting the one or more first bumps to the one or more second bumps to bond the silicon-based driving substrate with the organic light-emitting display device.

10. The method as claimed in claim 9, wherein the providing a silicon-based driving substrate, comprises:
providing a silicon substrate;
forming a driving device on a side of the silicon substrate;
forming a protection layer on a side of the driving device away from the silicon substrate to cover the driving device;
patterning the protection layer to define one or more second vias on the protection layer; and
forming the one or more first bumps on a side of the protection layer away from the driving device, wherein each of the one or more first bumps is connected to the driving device through a corresponding one of the one or more second vias.

11. The method as claimed in claim 9, wherein the plurality of first vias comprise one or more first sub-vias and one or more second sub-vias, the one or more second bumps comprise a first sub-bump and at least one second sub-bump, and the forming an organic light-emitting display device on a side of the glass substrate away from the second bump, comprises:
forming a spacer structure on a side of the glass substrate away from the one or more second bumps, wherein a plurality of pixel openings are defined on the spacer structure;
forming a first electrode in each of the plurality of pixel openings, wherein the first electrode is connected to the first sub-second bump through a corresponding one of the one or more first sub-vias;
forming a light-emitting device on a side of the first electrode away from the glass substrate; and
forming a second electrode on a side of the light-emitting device away from the first electrode, wherein the second electrode is connected to the at least one second sub-bump respectively through the one or more second sub-vias.

12. A display device, comprising:
a display panel, comprising:
a silicon-based driving substrate;
a glass substrate, disposed on a side of the silicon-based driving substrate and defining a plurality of first vias; and
an organic light-emitting display device, disposed on a side of the glass substrate away from the silicon-based driving substrate and bonded to the silicon-based driving substrate through at least one of the plurality of first vias; and
a power supply, configured to supply power to the display panel.

13. The display device as claimed in claim 12, wherein one or more first bumps are disposed on a side of the silicon-based driving substrate facing the glass substrate, one or more second bumps are disposed on a side of the glass substrate facing the silicon-based driving substrate, each of the one or more second bumps is connected to the organic light-emitting display device through a corresponding one of the plurality of first vias, and each of the one or more first bumps is connected to a corresponding one of the one or more second bumps, enabling the organic light-emitting display device to be bonded with the silicon-based driving substrate.

14. The display device as claimed in claim 13, wherein the silicon-based driving substrate comprises:
a silicon substrate;
a driving device, disposed on a side of the silicon substrate facing the glass substrate; and
a protection layer, covering the driving device and defining one or more second vias, wherein each of the one or more first bumps is connected to the driving device through a corresponding one of the one or more second vias.

15. The display device as claimed in claim 13, wherein the plurality of first vias comprise one or more first sub-vias and one or more second sub-vias, and the organic light-emitting display device comprises:
a spacer structure, disposed on a side of the glass substrate away from the silicon-based driving substrate and defining a plurality of pixel openings; and
a plurality of sub-pixels, disposed in the plurality of pixel openings, and each of the plurality of sub-pixels corresponding to one of the one or more first sub-vias.

16. The display device as claimed in claim 15, wherein the one or more second bumps comprise a first sub-bump and at least one second sub-bump, and each of the plurality of sub-pixels comprises:
a first electrode, disposed on a side of the glass substrate away from the silicon-based driving substrate and connected to the first sub-bump through a corresponding one of the one or more first sub-vias;
a light-emitting device, disposed on a side of the first electrode away from the glass substrate; and
a second electrode, disposed on a side of the light-emitting device away from the first electrode and connected to the at least one second sub-bump respectively through the one or more second sub-vias.

17. The display device as claimed in claim 16, wherein a third via is defined on the spacer structure, the third via is in communication with a corresponding one of the more than one second sub-vias, and the second electrode is connected to a corresponding one of the at least one second sub-bump through the third via and the corresponding one of the more than one second sub-vias.

18. The display device as claimed in claim 13, wherein each of the one or more first bumps and each of the one or more second bumps are both made of a conductive material.

19. The display device as claimed in claim 17, wherein the organic light-emitting display device further comprises a plurality of pixel units, each of the plurality of pixel units comprises more than one of the plurality of sub-pixels that are adjacent to each other, and the third via is defined on the spacer structure between any adjacent two of the plurality of pixel units.

20. The display device as claimed in claim 12, wherein the display device is configured in an AR device or a VR device.
